(19) United States
(12) Patent Application Publication
(10) Pub. No.: US 2025/0236741 A1
(43) Pub. Date: Jul. 24, 2025

(54) CURABLE COMPOSITION, FILM AND DISPLAY DEVICE USING THE SAME

(71) Applicant: Samsung Display Co., LTD., Yongin-si, Gyeonggi-do (KR)

(72) Inventors: Dong Wan RYU, Suwon-si (KR); Youngkwon KIM, Suwon-si (KR); Jiyoung JEONG, Suwon-si (KR); Jin Hee CHOI, Suwon-si (KR)

(21) Appl. No.: 18/837,479

(22) PCT Filed: Feb. 23, 2023
(86) PCT No.: PCT/KR2023/002576

§ 371 Date: Aug. 9, 2024

(30) Foreign Application Priority Data
Feb. 23, 2022 (KR) 10-2022-0023891

(51) Int. Cl. C09D 5/24; C08K 7/04; C08K 9/02; C09D 4/00; C09D 7/40; C09D 7/62; C09D 135/02; H10H 20/813; H10H 20/825; H10H 29/03

(52) U.S. Cl. CPC C09D 5/24; C09D 4/00; C09D 7/62; C09D 7/70; C09D 135/02; H10H 20/8132; H10H 20/825; H10H 29/03; C08K 7/04; C08K 9/02; C08K 2201/001; C08K 2201/003; C08K 2201/004

(57) ABSTRACT

A curable composition including (A) a semiconductor nanorod, (B) a photopolymerizable monomer including a compound having an unsaturated carbon-carbon double bond, (C) a photopolymerization initiator including a compound of a specific structure, and (D) a solvent, a film manufactured using the same, and a display device including the film are provided.

### CROSS-REFERENCE TO RELATED APPLICATION

The present application is a U.S. National Phase Patent Application of International Patent Application Number PCT/KR2023/002576, filed on Feb. 23, 2023, which claims priority to and the benefit of Korean Patent Application Number 10-2022-0023891, filed on Feb. 23, 2022, in the Korean Intellectual Property Office, the entire content of which is hereby incorporated by reference.

### BACKGROUND

### 1. Field

Embodiments of this disclosure relate to a curable composition, a film using the same, and a display device including the film.

### 2. Description of the Related Art

Light emitting diode (LED) development has been active at least since 1992, when Nakamura of Japan's Nichia Company succeeded in fusing high-quality single-crystal GaN nitride semiconductors by applying a low-temperature GaN compound buffer layer. An LED is a semiconductor that utilizes the characteristics of a compound semiconductor and has a structure in which an n-type semiconductor crystal, in which the majority of carriers are electrons, and a p-type semiconductor crystal, in which the majority of carriers are holes, are joined together. It converts electrical signals into light having a set or desired wavelength band and displays it. These LED semiconductors have high light conversion efficiency, consume very little energy, have a semi-permanent lifespan, and are environmentally friendly, so they have been called a revolution in light emission as green materials. Recently, with the development of compound semiconductor technology, high-brightness red, orange, green, blue, and white LEDs have been developed, and these can be used in many fields such as traffic lights, cell phones, automobile headlights, outdoor electronic signs, LCD BLU (back light units), and indoor and outdoor lighting, and active research thereof is continuing at home and abroad. For example, GaN-based compound semiconductors having a wide bandgap are used to manufacture LED semiconductors that emit light in the green, blue, and ultraviolet regions, and much research is being conducted on them because it is possible to produce white LED devices using blue LED devices. Among these series of studies, research is being actively conducted using ultra-small LED devices manufactured with the size of LEDs in nano or micro units (e.g., in nanometer or micrometer scale), and research is continuing to utilize these ultra-small LED devices for lighting and displays. Areas that continue to receive attention in these studies include electrodes that can apply power to ultra-small LED devices, electrode placement for purposes of use and reduction of space occupied by the electrodes, and methods of mounting ultra-small LEDs on the placed electrodes. Among these, the method of mounting ultra-small LED elements on the arranged electrodes still remains very difficult to place and mount the ultra-small LED elements on the electrodes as intended due to size constraints of the ultra-small LED elements. This is, at least in part, because ultra-small LED elements are nano-scale or micro-scale in size (e.g., nanometer or micrometer scale in size), so they cannot be individually placed and mounted in the target electrode area by human hands. Recently, the demand for nano-scale ultra-small LED devices is increasing, and attempts are being made to manufacture nano-scale GaN-based compound semiconductors or InGaN-based compound semiconductors as rods, but the dispersion stability of the nanorod itself is significantly reduced in the solution (or polymer compound). So far, development of technology that can enhance the dispersion stability of semiconductor nanorods in solutions (or polymer compounds) has been steadily underway, and as a result, technologies such as ligand treatment of semiconductor nanorods and solvents that improve the dispersion stability of semiconductor nanorods are being introduced one by one. However, no technology has yet been introduced for a curable composition including semiconductor nanorods, and there is no background knowledge about it.

### SUMMARY

One embodiment of the present disclosure provides a semiconductor nanorod-containing curable composition that can be cured at the i-Line (365 nm) wavelength, widely used in display manufacturing, without inhibiting the nanorod alignment characteristics in the dielectric migration process. Another embodiment provides a film manufactured using the curable composition. Another embodiment provides a display device including the film.

One embodiment of a semiconductor nanorod-containing curable composition includes (A) a semiconductor nanorod, (B) a photopolymerizable monomer including a compound having an unsaturated carbon-carbon double bond, (C) a photopolymerization initiator including a compound represented by the following Chemical Formula 1, and (D) a solvent.

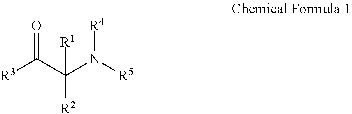

In Chemical Formula 1,

R¹ to R⁵ are each independently a hydrogen atom, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C20 aryl group, or a substituted or unsubstituted C3 to C20 heterocyclic group. R⁴ and R⁵ can, optionally, fuse with each other to form a ring. Chemical Formula 1 may be expressed as the following Chemical Formula 1-1 or Chemical Formula 1-2.

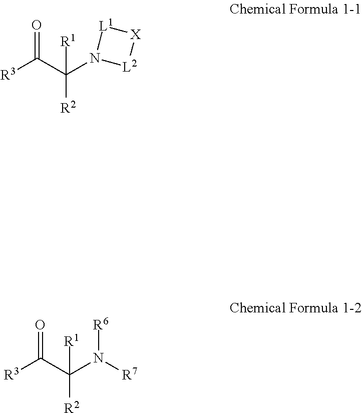

In Chemical Formula 1-1 and Chemical Formula 1-2,
X is CR^{a}R^{b} (R^{a} and R^{b} are each independently a hydrogen atom, a halogen atom, or a substituted or unsubstituted C1 to C10 alkyl group), O, or S,
L¹ and L² are each independently a substituted or unsubstituted C1 to C20 alkylene group,
R¹ to R³ are each independently a hydrogen atom, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C20 an aryl group, or a substituted or unsubstituted C3 to C20 heterocyclic group, and
R⁶ and R⁷ are each independently a hydrogen atom, a substituted or unsubstituted C1 to C20 alkyl group, a substituted or unsubstituted C3 to C20 cycloalkyl group, or a substituted or unsubstituted C6 to C20 aryl group. The compound represented by Chemical Formula 1 may be represented by the following Chemical Formula 1-1-1, Chemical Formula 1-2-1, or Chemical Formula 1-2-2.

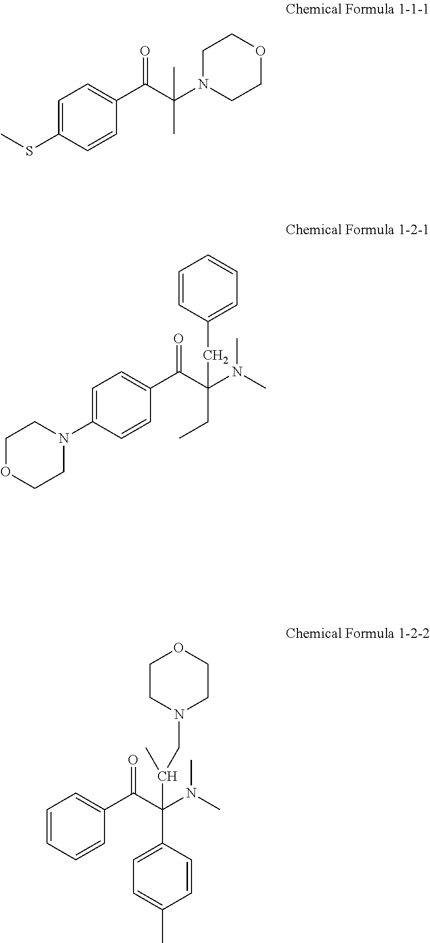 [SMILES: CSc1ccc(C(=O)C(C)(C)N2CCOCC2)cc1 ; CCC(Cc1ccccc1)(C(=O)c1ccc(N2CCOCC2)cc1)N(C)C ; Cc1ccc(C(C(=O)c2ccccc2)(C(C)CN2CCOCC2)N(C)C)cc1]

The semiconductor nanorod may have a diameter of 300 nm to 900 nm. The semiconductor nanorod may have a length of 3.5 μm to 5 μm. The semiconductor nanorod may include a GaN-based compound, an InGaN-based compound, or a combination thereof. The surface of the semiconductor nanorod may be coated with a metal oxide. The metal oxide may include alumina, silica, or a combination thereof. The curable composition includes 0.01% by weight to 10% by weight of the (A) semiconductor nanorod, based on the total amount of the curable composition; 1% to 40% by weight of the (B) photopolymerizable monomer; (C) 0.1% to 5% by weight of photopolymerization initiator; and it may include the remaining amount of the solvent (D). The curable composition may include malonic acid; 3-amino-1,2-propanediol; a silane-based coupling agent; a leveling agent; a fluorine-based surfactant; or it may include a combination thereof. Another embodiment provides a film manufactured using the curable composition. Another embodiment provides a display device including the film. Details of other aspects of embodiments of the disclosure are included in the detailed description below.

The composition according to one embodiment is a curable composition including semiconductor nanorods, has good dielectrophoresis, and can proceed with the patterning process after dielectrophoresis, thereby dramatically shortening the process time and process cost compared to existing compositions (improved process). It is also possible to implement fine linewidths according to embodiments of the present disclosure.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is an example of a cross-sectional view of a semiconductor nanorod used in a curable composition according to one embodiment.

FIG. 2 to FIG. 9 show the alignment and patterning process of semiconductor nanorods according to embodiments of the present disclosure.

FIG. 2 is a plan view showing coating a curable composition including semiconductor nanorods on an electrode according to an embodiment.

FIG. 3 is a plan view showing aligning (dielectrophoresis) semiconductor nanorods by applying an electric field according to embodiments of the present disclosure.

FIG. 4 is a cross-sectional view of semiconductor nanorods aligned on an electrode according to embodiments of the present disclosure.

FIG. 5 is a cross-sectional view showing a prebaking step after aligning the semiconductor nanorods according to embodiments of the present disclosure.

FIG. 6 is a cross-sectional view showing coating the photoresist after prebaking and exposing it to light according to embodiments of the present disclosure.

FIG. 7 is a cross-sectional view showing development after exposure according to embodiments of the present disclosure.

FIG. 8 is a cross-sectional view showing forming a fixed film by etching after development according to embodiments of the present disclosure.

FIG. 9 is a cross-sectional view showing a film formed on semiconductor nanorods aligned on an electrode according to embodiments of the present disclosure.

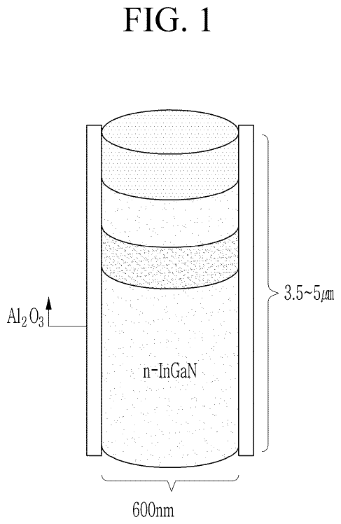

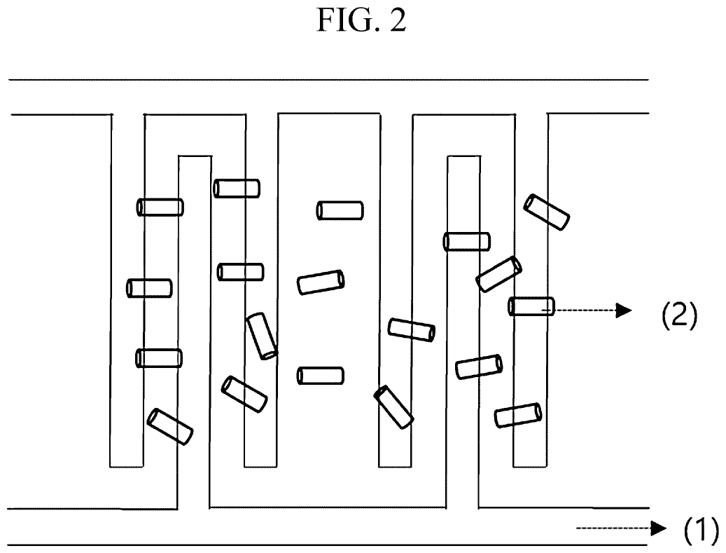

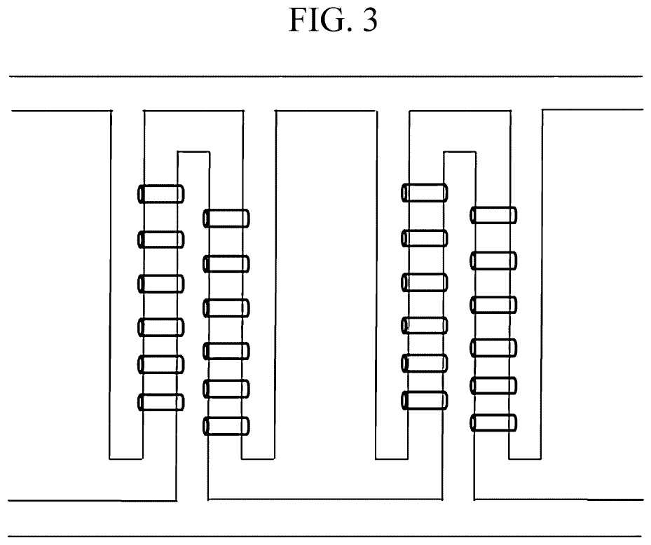

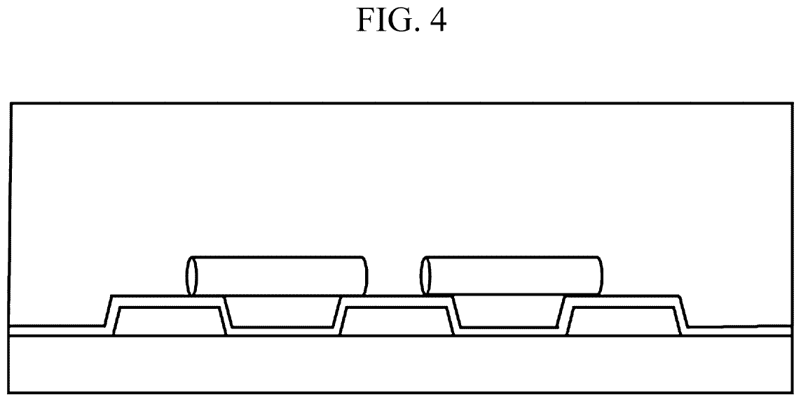

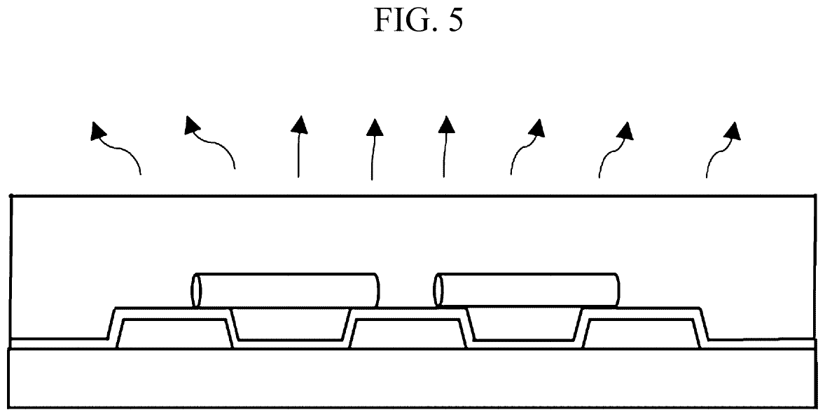

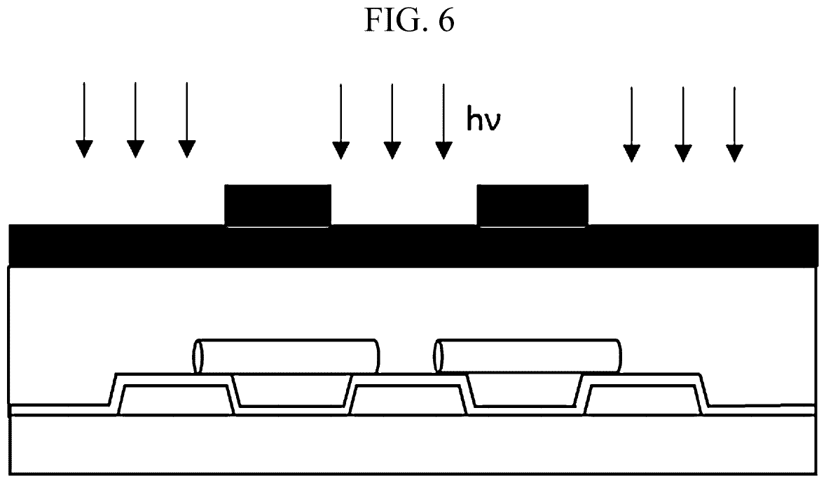

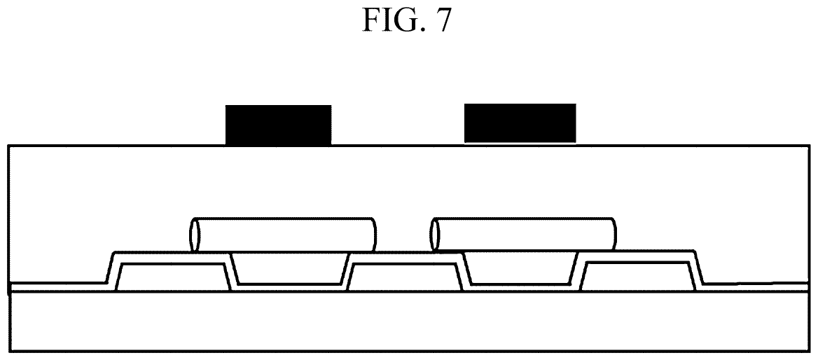

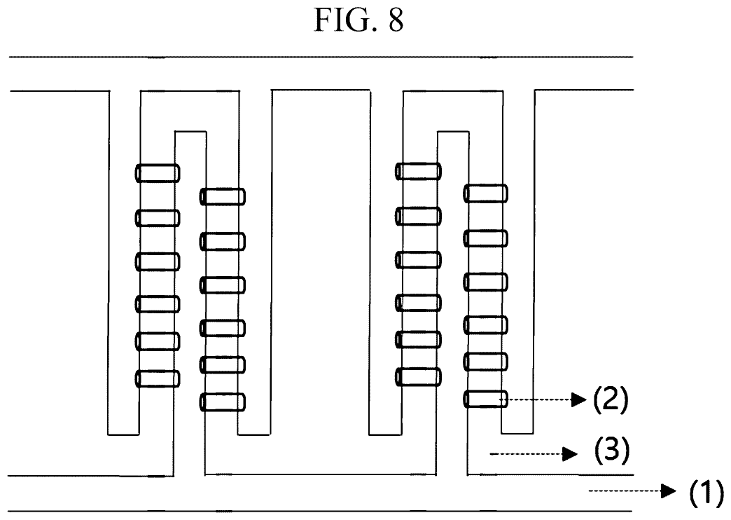

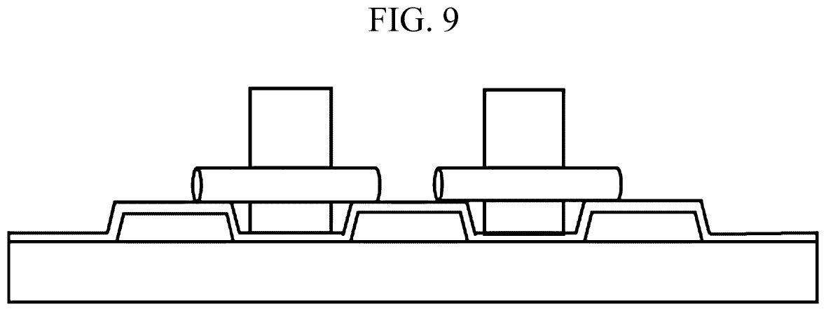

### DETAILED DESCRIPTION

Hereinafter, embodiments of the present disclosure will be described in more detail. However, the following are presented as examples, and the present disclosure is not limited thereby, and the present disclosure is only defined by the scope of the appended claims, and equivalents thereof.

Unless otherwise specified herein, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

Unless otherwise specified herein, “substitution” means that at least one hydrogen atom is replaced by a halogen atom (F, Cl, Br, I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or its salt, a sulfonic acid group or its salt, a phosphoric acid group or its salt, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

Also, unless otherwise specified herein, “hetero” means that at least one hetero atom of N, O, S, and P is included in the Chemical Formula.

Also, unless otherwise specified in the specification, “(meth)acrylate” means that both “acrylate” and “methacrylate” are possible, and “(meth)acrylic acid” means “acrylic acid” and “methacrylic acid.”

Unless otherwise specified herein, “combination” means mixing and/or copolymerization.

Unless otherwise defined in the Chemical Formulas in this specification, if a chemical bond is not drawn at a position where a chemical bond should be drawn, it means that a hydrogen atom is bonded at that position.

Also, unless otherwise specified herein, “*” refers to a portion connected to the same or different atom or Chemical Formula.

The curable composition according to one embodiment includes (A) a semiconductor nanorod; (B) a photopolymerizable monomer including a compound having an unsaturated carbon-carbon double bond; (C) a photopolymerization initiator including a compound represented by the following Chemical Formula 1; and (D) a solvent, and when an electric field is applied to the composition coated on the electrode, the semiconductor nanorods are aligned, thereby dramatically reducing the cost of complex and expensive processes for a u-LED, a mini-LED, etc.

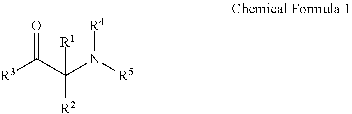

In Chemical Formula 1,
R¹ to R⁵ are each independently a hydrogen atom, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C20 aryl group, or a substituted or unsubstituted C3 to C20 heterocyclic group, and
R⁴ and R⁵ can, optionally, fuse with each other to form a ring.

For the electrophoresis of semiconductor nanorods as light emitting devices, semiconductor nanorod dispersions may be inkjet and/or slit coated, where a high dielectric constant of the semiconductor nanorod solution is a parameter for the production of large area coatings and panels. After alignment of semiconductor nanorods, a cleaning process for post-processing is essential, but in the absence of a fixing film, the aligned semiconductor nanorods may be lost during cleaning, so the fixing film capable of fixing semiconductor nanorods has become necessary, but to date, no organic material has been used as such a fixing film. This fixed film utilizes the formation of a line having a thickness of 3 μm to 5 μm and a width of 2.0 μm or less.

One embodiment is a curable composition including semiconductor nanorods, which is a material that allows a patterning process to be performed after dielectrophoresis, thereby shortening the process.

Photosensitive resin compositions used in existing displays and electronic materials include inorganic dispersions (quantum dots, pigments, dyes, light diffusers, etc.), photoinitiators, acrylic (and/or cardo) binders, acrylic monomers, and organic solvents, after exposing the pattern using the acidity of the carboxyl group of the cardo-based polymer binder, patterning was created by dissolving the non-exposed area (non-cured area) using an alkaline solution such as KOH and/or TMAH. At this time, a photopolymerization initiator that triggers the photopolymerization reaction upon exposure to light is utilized, but many existing photopolymerization initiators are strongly polar or ionic, which can adversely affect the alignment of the nanorods, especially in the dielectrophoresis process.

However, the curable composition according to one embodiment is a negative composition including semiconductor nanorods, has good dielectrophoretic properties, can proceed with a patterning process after dielectrophoresis, and can form a fixed film after post-baking, so in terms of processability, not only is it very beneficial, but it can also be cured at an i-Line (365 nm) wavelength, which is widely used in display manufacturing, without impairing the nanorod alignment characteristics in the dielectrophoresis process.

Below, each component is described in more detail.

### (A) Semiconductor Nanorod

The semiconductor nanorod may include a GaN-based compound, an InGaN-based compound, or a combination thereof, and its surface may be coated with a metal oxide.

For the dispersion stability of the semiconductor nanorod solution (semiconductor nanorod solvent), approximately 3 hours are usually utilized, which is an insufficient amount of time to perform a large-area inkjet process. Accordingly, by coating the surface of the semiconductor nanorod with a metal oxide including alumina, silica, or a combination thereof to form an insulating film (e.g., an electrically insulating film including, for example, Al₂O₃, SiOₓ, or a combination thereof), compatibility with solvents described later can be maximized or increased.

For example, the semiconductor nanorod may have a diameter of 300 nm to 900 nm, for example, 600 nm to 700 nm.

For example, the semiconductor nanorod may have a length of 3.5 μm to 5 μm.

When the semiconductor nanorod has the above diameter and length, surface coating with the metal oxide can be easily done, and the dispersion stability of the semiconductor nanorod can be maximized or increased.

The semiconductor nanorod may be included in an amount of 0.01 wt % to 10 wt %, for example, 0.01 wt % to 5 wt %, or for example, 0.01 wt % to 3 wt %, based on the total amount of the curable composition. When the semiconductor nanorod is included within the above ranges, the dispersibility within the composition is good, and the manufactured pattern can have a fine line width.

### (B) Photopolymerizable Monomer

The photopolymerizable monomer includes a compound having an unsaturated carbon-carbon double bond. For example, the compound having the unsaturated carbon-carbon double bond may be a mono- or polyfunctional ester of (meth)acrylic acid having at least one ethylenically unsaturated double bond.

Because the photopolymerizable monomer includes a compound having the ethylenically unsaturated double bond, suitable or sufficient polymerization occurs during exposure to light in the pattern formation process, thereby forming a pattern having excellent heat resistance, light resistance, and chemical resistance.

For example, the compound having the unsaturated carbon-carbon double bond may be an acrylate-based compound, such as an aliphatic acrylate-based compound. The dielectric properties may be slightly reduced when the compound having the unsaturated carbon-carbon double bond is an aromatic acrylate compound, compared to when using an aliphatic acrylate compound, therefore, it may be suitable to use an aliphatic acrylate compound for the compound having the unsaturated carbon-carbon double bond.

Examples of the compound having the above-mentioned unsaturated carbon-carbon double bond include ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethyl ether(meth)acrylate, trimethylolpropane tri(meth)acrylate, tris(meth)acryloxyethyl phosphate, novolac epoxy(meth)acrylate, etc.

Examples of commercially available products of compounds having the unsaturated carbon-carbon double bond are as follows. Examples of the monofunctional ester of the above (meth)acrylic acid include Aroonix M-101®, M-111®, M-114® etc. from Toagosei Co., Ltd., KAYARAD TC-110S®, TC-120S® etc. from Nihon Kayaku Co., Ltd.; V-158®, V-2311® etc. from Osaka Yukigaku Co., Ltd. Examples of the above-mentioned difunctional ester of (meth)acrylic acid include Aronics M-210®, M-240®, and M-6200® manufactured by Toagosei Chemical Co., Ltd.; Nihon Kayaku Co., Ltd.'s KAYARAD HDDA®, HX-220®, R-604®, etc.; examples include V-260®, V-312®, and V-335 HP® manufactured by Osaka Yuki Chemical Co., Ltd. Examples of the trifunctional ester of (meth)acrylic acid include Aronics M-309®, M-400®, M-405®, M-450®, and M manufactured by Toagosei Chemical Co., Ltd. M-7100®, M-8030®, M-8060®, etc.; KAYARAD TMPTA®, DPCA-20®, DPCA-30®, DPCA-60®, DPCA-120®, etc. from Nihon Kayaku Co., Ltd.; and examples include V-295®, V-300®, V-360®, V-GPT®, V-3PAR, and V-400® manufactured by Osaka Yuki Kayaku Kogyo Co., Ltd. The above products can be used alone or in combination of two or more types (or kinds).

For example, the compound having the unsaturated carbon-carbon double bond may be at least one compound selected from the group consisting of the following Chemical Formulas M-1 to Chemical Formula M-5, but is not necessarily limited thereto.

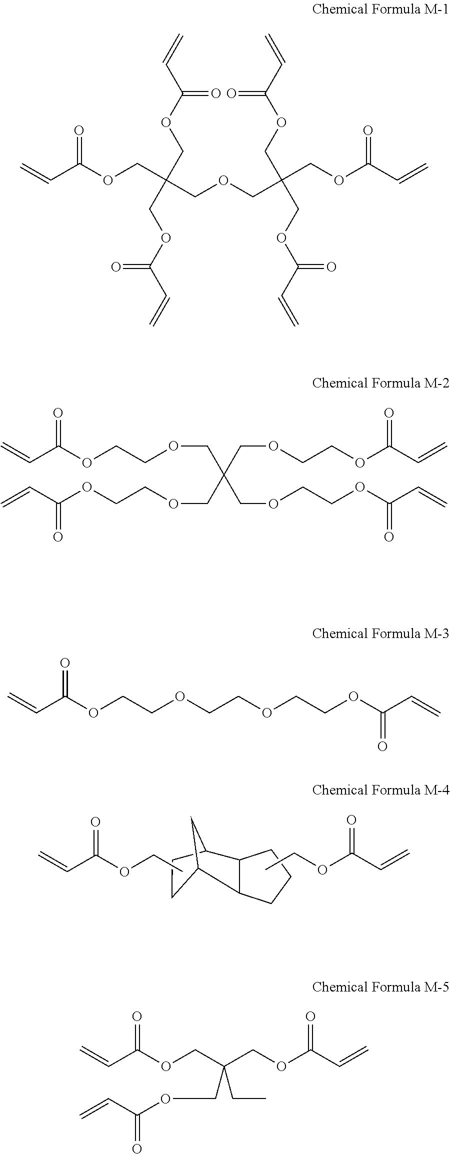

The photopolymerizable monomer may be used after being treated with an acid anhydride to provide better developability.

The photopolymerizable monomer may be included in an amount of 1% to 40% by weight, such as 3% to 30% by weight, such as 5% to 25% by weight, based on the total amount of the curable composition. When the photopolymerizable monomer is included within the above ranges, it is possible to form a pattern that has excellent electrophoretic properties, is suitably or sufficiently cured upon exposure to light in the pattern formation process, has excellent reliability, and has excellent heat resistance, light resistance, chemical resistance, resolution, and adhesion.

### (C) Photopolymerization Initiator

A photopolymerization initiator according to one embodiment includes a compound represented by Chemical Formula 1 above.

For example, Chemical Formula 1 may be expressed as Chemical Formula 1-1 or Chemical Formula 1-2 below.

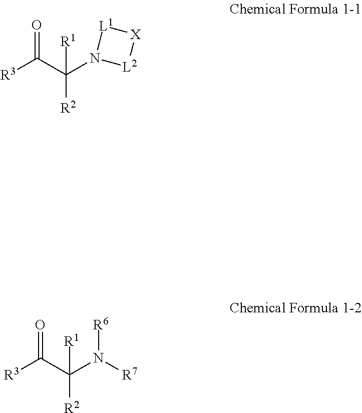

In Chemical Formula 1-1 and Chemical Formula 1-2,
X is CRaRb (where Ra and Rb are each independently a hydrogen atom, a halogen atom, or a substituted or unsubstituted C1 to C10 alkyl group), O, or S,
L1 and L2 are each independently a substituted or unsubstituted C1 to C20 alkylene group,
R1 to R3 are each independently a hydrogen atom, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C20 an aryl group, or a substituted or unsubstituted C3 to C20 heterocyclic group,
R6 and R7 are each independently a hydrogen atom, a substituted or unsubstituted C1 to C20 alkyl group, a substituted or unsubstituted C3 to C20 cycloalkyl group, or a substituted or unsubstituted C6 to C20 aryl group.

The compound represented by Chemical Formula 1-1 or Chemical Formula 1-2 can improve the dielectrophoretic properties of the curable composition when used together with nanorods and acrylic photopolymerizable monomers.

For example, the compound represented by Chemical Formula 1 may be represented by the following Chemical Formula 1-1-1, Chemical Formula 1-2-1, or Chemical Formula 1-2-2, but is not necessarily limited thereto.

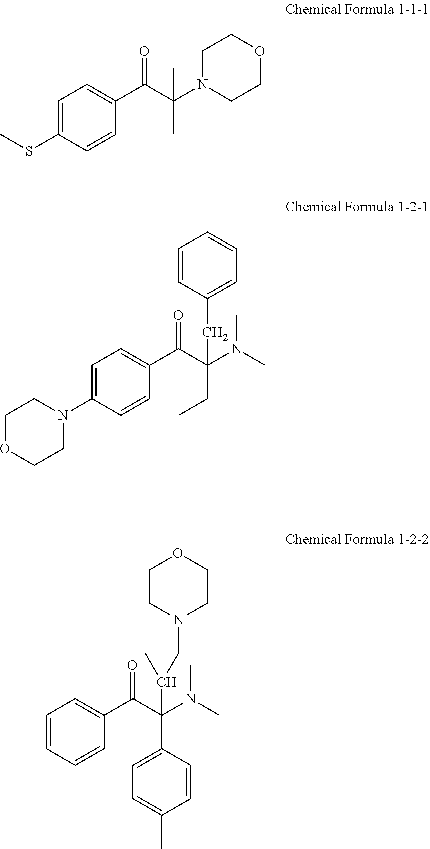 [SMILES: CSc1ccc(C(=O)C(C)(C)N2CCOCC2)cc1 ; CCC(Cc1ccccc1)(C(=O)c1ccc(N2CCOCC2)cc1)N(C)C ; Cc1ccc(C(C(=O)c2ccccc2)(C(C)CN2CCOCC2)N(C)C)cc1]

In embodiments, the photopolymerization initiator may further include, in addition to the compound represented by Chemical Formula 1, an acetophenone-based compound, a benzophenone-based compound, a thioxanthone-based compound, a benzoin-based compound, a triazine-based compound, an oxime-based compound, etc.

Examples of the acetophenone compounds include 2,2′-diethoxyacetophenone, 2,2′-dibutoxyacetophenone, 2-hydroxy-2-methylpropiophenone, p-t-butyltrichloroacetophenone, p-t-butyldichloroacetophenone, 4-chloroacetophenone, 2,2′-dichloro-4-phenoxyacetophenone, 2-methyl-1-(4-(methylthio)phenyl)-2-morpholinopropane-1-one, 2-benzyl-2-dimethylamino-1-(4-morpholinophenyl)-butan-1-one, etc.

Examples of the benzophenone-based compounds include benzophenone, benzoylbenzoic acid, methyl benzoyl benzoate, 4-phenylbenzophenone, hydroxybenzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, 3,3′-dimethyl-2-methoxybenzophenone, etc.

Examples of the thioxanthone-based compounds include thioxanthone, 2-methylthioxanthone, isopropylthioxanthone, 2,4-diethylthioxanthone, 2,4-diisopropylthioxanthone, 2-chlorothioxanthone, etc.

Examples of the benzoin-based compound include benzoin, benzoin methyl ether, benzoin ethyl ether, benzoin isopropyl ether, benzoin isobutyl ether, and benzyl dimethyl ketal.

Examples of the triazine-based compounds include 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloromethyl)-s-triazine, bis(trichloromethyl)-6-styryl-s-triazine, 2-(naphtho-1-yl)-4,6-bis(trichloromethyl)-s-triazine, 2-(4-methoxynaphtho-1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, etc.

Examples of the oxime-based compounds include O-acyloxime-based compounds, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, etc. Examples of the O-acyloxime compounds include 1,2-octanedione, 2-dimethylamino-2-(4-methylbenzyl)-1-(4-morpholin-4-yl-phenyl)-butane-1-one, 1-(4-phenylsulfanylphenyl)-butane-1,2-dione-2-oxime-O-benzoate, 1-(4-phenylsulfanylphenyl)-octane-1,2-dione-2-oxime-O-benzoate, 1-(4-phenylsulfanylphenyl)-octane-1-oneoxime-O-acetate, 1-(4-phenylsulfanylphenyl)-butan-1-oneoxime-O-acetate, etc.

In addition to the above compounds, the photopolymerization initiator may further include carbazole-based compounds, diketone-based compounds, sulfonium borate-based compounds, diazo-based compounds, imidazole-based compounds, and/or biimidazole-based compounds.

1 The photopolymerization initiator may be used together with a photosensitizer that absorbs light, becomes excited, and then transmits energy to cause a chemical reaction.

Examples of the photosensitizer include tetraethylene glycol bis-3-mercaptopropionate, pentaerythritol tetrakis-3-mercaptopropionate, dipentaerythritol tetrakis-3-mercaptopropionate, etc.

The photopolymerization initiator may be included in an amount of 0.1 wt % to 5 wt %, for example, 0.1 wt % to 3 wt %, based on the total amount of the curable composition. When the photopolymerization initiator is included within the above ranges, electrophoretic properties are not impaired, photopolymerization suitably or sufficiently occurs upon exposure in the pattern formation process, and a decrease in transmittance due to unreacted initiator can be prevented or reduced.

### (D) a Solvent

The solvent may be a material that is compatible with, but does not react with, the semiconductor nanorod, the photopolymerizable monomer, and the photopolymerization initiator.

Examples of the solvent include alcohols such as methanol and ethanol; ethers such as dichloroethyl ether, n-butyl ether, diisoamyl ether, methylphenyl ether, and tetrahydrofuran; glycol ethers such as ethylene glycol methyl ether, ethylene glycol ethyl ether, and propylene glycol methyl ether; cellosolve acetates such as methyl cellosolve acetate, ethyl cellosolve acetate, and diethyl cellosolve acetate; carbitols such as methyl ethyl carbitol, diethyl carbitol, diethylene glycol monomethyl ether, diethylene glycol monoethyl ether, diethylene glycol dimethyl ether, diethylene glycol methyl ethyl ether, and diethylene glycol diethyl ether; propylene glycol alkyl ether acetates such as propylene glycol methyl ether acetate and propylene glycol propyl ether acetate; aromatic hydrocarbons such as toluene and xylene; ketones such as methyl ethyl ketone, cyclohexanone, 4-hydroxy-4-methyl-2-pentanone, methyl-n-propyl ketone, methyl-n-butyl ketone, methyl-n-amyl ketone, and 2-heptanone, saturated aliphatic monocarboxylic acid alkyl esters such as ethyl acetate, n-butyl acetate, and isobutyl acetate; lactic acid alkyl esters such as methyl lactate and ethyl lactate; hydroxyacetic acid alkyl esters such as methyl hydroxyacetate, ethyl hydroxyacetate, and butyl hydroxyacetate; acetic acid alkoxyalkyl esters such as methoxymethyl acetate, methoxyethyl acetate, methoxybutyl acetate, ethoxymethyl acetate, and ethoxyethyl acetate; 3-hydroxypropionic acid alkyl esters such as methyl 3-hydroxypropionate and ethyl 3-hydroxypropionate, 3-alkoxypropionic acid alkyl esters such as methyl 3-methoxypropionate, ethyl 3-methoxypropionate, ethyl 3-ethoxypropionate, and methyl 3-ethoxypropionate; 2-hydroxypropionic acid alkyl esters such as methyl 2-hydroxypropionate, ethyl 2-hydroxypropionate, and propyl 2-hydroxypropionate; 2-alkoxypropionic acid alkyl esters such as methyl 2-methoxypropionate, ethyl 2-methoxypropionate, ethyl 2-ethoxypropionate, and methyl 2-ethoxypropionate; 2-hydroxy-2-methylpropionic acid alkyl esters such as methyl 2-hydroxy-2-methylpropionate and ethyl 2-hydroxy-2-methylpropionate, 2-alkoxy-2-methylpropionic acid alkyl esters such as methyl 2-methoxy-2-methylpropionate and ethyl 2-ethoxy-2-methylpropionate; esters such as 2-hydroxyethyl propionate, 2-hydroxy-2-methylethyl propionate, hydroxyethyl acetate, and methyl 2-hydroxy-3-methylbutanoate; and in embodiments, there are compounds of keto acid esters such as ethyl pyruvate, and also N-methylformamide, N, N-dimethylformamide, N-methylformanilide, N-methylacetamide, and N, N-dimethylacetamide; N-methylpyrrolidone, dimethyl sulfoxide, benzyl ethyl ether, dihexyl ether, acetonylacetone, isophorone, caproic acid, caprylic acid, 1-octanol, 1-nonanol, benzyl alcohol, and benzyl acetate; and in embodiments, there are ethyl benzoate, diethyl oxalate, diethyl maleate, γ-butyrolactone (GBL), ethylene carbonate, propylene carbonate, phenyl cellosolve acetate, etc., and these can be used alone or in a mixture of two or more types (or kinds).

Considering miscibility and reactivity in the solvent, glycol ethers such as ethylene glycol monoethyl ether, ethylene glycol alkyl ether acetates such as ethyl cellosolve acetate; esters such as 2-hydroxyethyl propionate, diethylene glycols such as diethylene glycol monomethyl ether, propylene glycol alkyl ether acetates such as propylene glycol monomethyl ether acetate and propylene glycol propyl ether acetate may be used.

The solvent is present in a balance of, for example, 55% to 91% by weight, such as 55% to 90% by weight, such as 55% to 85% by weight, such as 56% to 84% by weight, such as 57% by weight, based on the total amount of the curable composition. It may include from 59% to 83% by weight, such as from 58% to 82% by weight, such as from 59% to 81% by weight, such as from 59% to 80% by weight. When the solvent is included within the above ranges, the curable composition has excellent applicability and a coating film having excellent flatness can be obtained.

### (E) Other Additives

The curable composition according to one embodiment includes malonic acid, 3-amino-1,2-propanediol; a silane-based coupling agent, a leveling agent, a fluorine-based surfactant, or a combination thereof.

For example, the curable composition may include a silane-based coupling agent having a reactive substituent such as a vinyl group, a carboxyl group, a methacryloxy group, an isocyanate group, and/or an epoxy group to improve adhesion to the substrate.

Examples of the silane-based coupling agent include trimethoxysilyl benzoic acid, γ-methacryl oxypropyl trimethoxysilane, vinyl triacetoxysilane, vinyl trimethoxysilane, γ-isocyanate propyl triethoxysilane, and γ-gly. Examples include sidoxy propyl trimethoxysilane, β-(3,4-epoxycyclohexyl)ethyltrimethoxysilane, and these can be used alone or in a mixture of two or more types (or kinds).

The silane-based coupling agent may be included in an amount of 0.01 to 10 parts by weight based on 100 parts by weight of the curable composition. When the silane-based coupling agent is included within the above range, adhesion and storage properties are excellent.

In embodiments, the curable composition may further include a surfactant, such as a fluorine-based surfactant, if necessary or desired, to improve coating properties and prevent or reduce occurrence of defects.

Examples of the fluorine-based surfactants include BM-1000® and BM-1100® from BM Chemie; Mecha pack F 142DR, F 172®, F 173®, F 183®, etc. from Dai Nippon Inki Chemicals Co., Ltd.; Sumitomo 3M Co., Ltd. Prorad FC-135®, FC-170C®, FC-430® FC-431®, etc.; Asahi Grass Co., Ltd.'s Saffron S-112®, S-113®, S-131®, S-141®, S-145®, etc.; SH-28PA®, SH-190®, SH-193®, SZ-6032®, SF-8428®, etc. from Toray Silicone Co., Ltd.; fluorine-based surfactants commercially available under names such as F-482, F-484, F-478, and F-554 from DIC Co., Ltd, etc.

The fluorine-based surfactant may be used in an amount of 0.001 to 5 parts by weight based on 100 parts by weight of the curable composition. When the fluorine-based surfactant is included within the above range, coating uniformity is ensured or improved, stains do not occur, and wetting on the glass substrate is excellent.

In embodiments, a certain amount of other additives such as antioxidants and stabilizers may be added to the curable composition within a range that does not impair the physical properties of the curable composition or the resultant film.

### Binder Resin

The curable composition may further include a binder resin.

The binder resin may include an acrylic binder resin, a cardo-based binder resin, or a combination thereof.

The acrylic binder resin and cardo-based resin can be any suitable resin generally used in curable compositions or photosensitive compositions, and the binder resin is not limited to a specific type (or kind).

The binder resin may be included in an amount of 1% to 30% by weight, for example, 1% to 20% by weight, based on the total amount of the curable composition. When the binder resin is included within the above ranges, the curing shrinkage rate can be lowered.

Another embodiment provides a film prepared using the curable composition described above.

An embodiment of the manufacturing method of the film is as follows.

### (1) Application and Film Formation Stage

The curable composition is applied onto an electrode substrate that has undergone a certain pretreatment, using methods such as spin and/or slit coating, roll coating, screen printing, an applicator method, etc., to a set or desired thickness, for example, a thickness of 1.2 μm to 3.5 μm, and after aligning the nanorods by dielectric movement, the film is formed by removing the solvent by heating (pre-baking) at a temperature of 70° C. to 100° C. for 1 to 10 minutes.

### (2) Exposure Step

In order to form the pattern required or suitable for the obtained coating film, another photoresist and a mask of a set or predetermined shape are interposed, and then 200 nm to 500 nm active rays are irradiated. Light sources used for irradiation include low-pressure mercury lamps, high-pressure mercury lamps, ultra-high pressure mercury lamps, metal halide lamps, and argon gas lasers. In some cases, X-rays and electron beams can also be used.

The exposure amount varies depending on the type (or kind), mixing amount, and dry film thickness of each component of the curable composition, but is, for example, 500 mJ/cm² or less (based on a 365 nm sensor) when using a high-pressure mercury lamp.

### (3) Development Stage

Following the exposure, an alkaline aqueous solution is used as a developer to dissolve and remove unnecessary parts, leaving only the exposed parts remaining to form an image pattern.

### (4) Etching Step

The image pattern obtained by the above development is etched to obtain a pattern that is excellent in terms of heat resistance, light resistance, adhesion, crack resistance, chemical resistance, high strength, storage stability, etc., to obtain a fixed organic film.

Another embodiment provides a display device including the film.

### EXAMPLES

Hereinafter, example embodiments of the present disclosure will be described. However, the following examples are only example embodiments of the present disclosure, and the present disclosure is not limited by the following examples.

### Preparation of Curable Composition

### 1. Isolation of Semiconductor Nanorod

40 ml of stearic acid (1.5 mM) was reacted with a nanorod patterned InGaN wafer (4 inch) at room temperature (23° C.) for 4 hours. After reaction, the nanorod patterned InGaN wafer was soaked in 50 ml of acetone for 5 minutes to remove excess stearic acid, and additionally rinsed with 40 ml of acetone. The cleaned nanorod patterned InGaN wafer was placed in a 27 KW bath type sonicator with 35 ml of GBL, and nanorods were separated from the nanorod patterned InGaN wafer surface using sonication for 5 minutes. The separated nanorods were placed in a FALCON tube exclusively for centrifugation and 10 ml of GBL was added to further wash the nanorods on the bath surface. The nanorods were centrifuged at 4000 rpm for 10 minutes, the supernatant was discarded, the precipitate was redispersed in acetone (40 ml), and foreign substances were filtered out using a 10 μm mesh filter. After additional centrifugation (4000 rpm, 10 minutes), the precipitate was dried in a drying oven (100° C., 1 hour) and then weighed.

### 2. Preparation of Curable Composition

After dissolving the photopolymerization initiator in the solvent, the photopolymerization initiator was sufficiently stirred at room temperature for 30 minutes. Next, photopolymerizable monomers and additives were added and stirred at room temperature for another hour. After stirring, the separated nanorods were added and stirred sufficiently for 1 hour to prepare a curable composition including nanorods.

Curable compositions according to Examples 1 to 8 and Comparative Examples 1 and 4 were prepared with the compositions shown in Tables 1 and 2 below using the components mentioned below. The structures of the photopolymerizable monomer and photopolymerization initiator are shown in Table 3 below.

TABLE 1
(unit: g)

| | | Exam- | Exam- | Exam- | Exam- | Exam- | Exam- | Exam- | Exam- |
|---|---|---|---|---|---|---|---|---|---|
| | | ple 1 | ple 2 | ple 3 | ple 4 | ple 5 | ple 6 | ple 7 | ple 8 |
| (A) | | 0.20 | 0.20 | 0.20 | 0.20 | 0.20 | 0.20 | 0.20 | 0.20 |
| Semiconductor | | | | | | | | | |
| nanorod | | | | | | | | | |
| (B) | B-1 | 20.00 | — | — | 20.00 | — | — | 20.00 | — |
| Photopolymerization | B-2 | — | 20.00 | — | — | 20.00 | — | — | — |
| monomer | B-3 | — | — | 20.00 | — | — | 20.00 | — | — |
| | B-4 | — | — | — | — | — | — | — | 20.00 |
| (C) | C-1 | 0.3 | 0.3 | 0.3 | — | — | — | — | 0.3 |
| Photopolymerization | C-2 | — | — | — | 0.3 | 0.3 | 0.3 | — | — |
| initiator | C-3 | — | — | — | — | — | — | 0.3 | — |
| | C-4 | — | — | — | — | — | — | — | — |
| | C-5 | — | — | — | — | — | — | — | — |
| | C-6 | — | — | — | — | — | — | — | — |
| | C-7 | — | — | — | — | — | — | — | — |
| | C-8 | — | — | — | — | — | — | — | — |

| | | | | | | | | |
|---|---|---|---|---|---|---|---|---|
| (D) Solvent | 79.49 | 79.49 | 79.49 | 79.49 | 79.49 | 79.49 | 79.49 | 79.49 |
| (E) Additive | 0.01 | 0.01 | 0.01 | 0.01 | 0.01 | 0.01 | 0.01 | 0.01 |

TABLE 2
(unit: g)

| | | Comparative | Comparative | Comparative | Comparative |
|---|---|---|---|---|---|
| | | Example 1 | Example 2 | Example 3 | Example 4 |
| (A) Semiconductor | | 0.20 | 0.20 | 0.20 | 0.20 |
| nanorod | | | | | |
| (B) | B-1 | 20.00 | 20.00 | 20.00 | 20.00 |
| Photopolymer- | B-2 | — | — | — | — |
| ization monomer | B-3 | — | — | — | — |
| (C) | C-1 | — | — | — | — |
| Photopolymer- | C-2 | — | — | — | — |
| ization | C-3 | — | — | — | — |
| initiator | C-4 | 0.3 | — | — | — |
| | C-5 | — | 0.3 | — | — |
| | C-6 | — | — | 0.3 | — |
| | C-7 | — | — | — | 0.3 |

| | | | | |
|---|---|---|---|---|
| (D) Solvent | 79.49 | 79.49 | 79.49 | 79.49 |
| (E) Additive | 0.01 | 0.01 | 0.01 | 0.01 |

### (A) Semiconductor Nanorod

InGaN nano rod (diameter: 600˜800 nm, length: 3.5˜5 μm)

### (B) Photopolymerization Monomer

See Table 3 below.

### (C) Photopolymerization Initiator

See Table 3 below.

### (D) Solvent

Triethyl-2-acetylcitrate (Aldrich)

### (F) Other Additives

Fluorine-based surfactant (F-554, DIC)

TABLE 3

| Type | Mark | Chemical structure | Name, maker |
|---|---|---|---|
| photopolymerization monomer | B-1 | 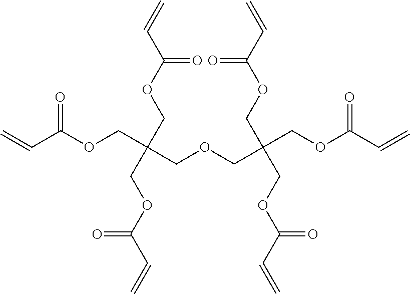 [SMILES: C=CC(=O)OCC(COCC(COC(=O)C=C)(COC(=O)C=C)COC(=O)C=C)(COC(=O)C=C)COC(=O)C=C] | DPHA (Nippon Kayaku company) |
| | B-2 | 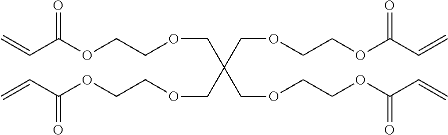 [SMILES: C=CC(=O)OCCOCC(COCCOC(=O)C=C)(COCCOC(=O)C=C)COCCOC(=O)C=C] | PE044 (Hannong) |
| | B-3 | 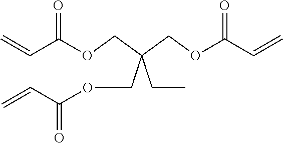 [SMILES: C=CC(=O)OCC(CC)(COC(=O)C=C)COC(=O)C=C] | TP003 (Hannong) |
| | B-4 | 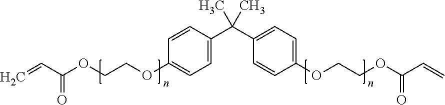 | Photomer 4028 (IGM Resins company) |
| photopolymerization initiator | C-1 | 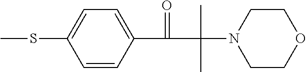 [SMILES: CSc1ccc(C(=O)C(C)(C)N2CCOCC2)cc1] | Omnirad 907 (IGM Resins company) |
| | C-2 | 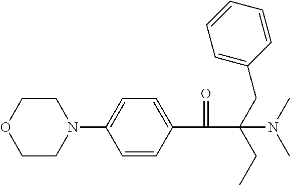 [SMILES: CCC(Cc1ccccc1)(C(=O)c1ccc(N2CCOCC2)cc1)N(C)C] | Omnirad 369 (IGM Resins company) |
| | C-3 | 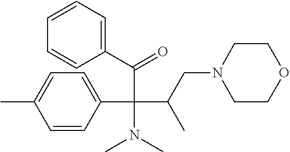 [SMILES: Cc1ccc(C(C(=O)c2ccccc2)(C(C)CN2CCOCC2)N(C)C)cc1] | Omnirad 379 (IGM Resins company) |
| | C-4 | 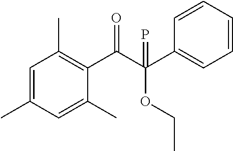 | Omnirad TPO-L (IGM Resins company) |
| | C-5 | 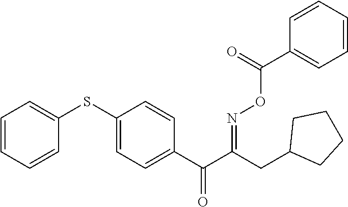 [SMILES: O=C(O/N=C(\CC1CCCC1)C(=O)c1ccc(Sc2ccccc2)cc1)c1ccccc1] | PBG305 (Tronly company) |
| | C-6 | 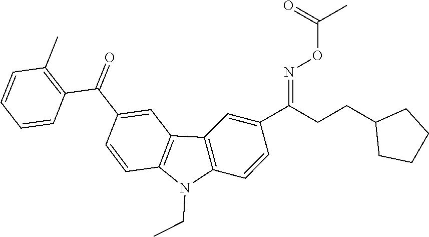 [SMILES: CCn1c2ccc(C(=O)c3ccccc3C)cc2c2cc(/C(CCC3CCCC3)=N/OC(C)=O)ccc21] | PBG304 (Tronly company) |
| | C-7 | 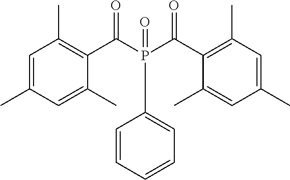 | Omnirad 819 (IGM Resins company) |

### Evaluation: Dielectrophoretic Properties

The dielectrophoretic properties (bias alignment, central alignment) of each of the nanorod-containing curable compositions of Examples 1 to 8 and Comparative Examples 1 to 4 were measured using Turbiscan, and the results are shown in Table 4 below.

Specifically, the method of measuring dielectrophoretic properties is as follows.

First, 500 μl of the curable composition was applied to Thin-film Gold basic interdigitated linear electrodes (ED-CIDE4-Au, Micrux), an electric field (25 KHz, +30 v) was applied, followed by 1 minute of waiting. After drying the solvent using a hot plate, the dielectrophoresis characteristics were evaluated by checking the aligned number (ea.) and the unaligned number (ea.) in the center between electrodes using a microscope.

TABLE 4

| | | | | | | | | | Compar- | Compar- | Compar- | Compar- |
|---|---|---|---|---|---|---|---|---|---|---|---|---|
| | | | | | | | | | ative | ative | ative | ative |
| | Exam- | Exam- | Exam- | Exam- | Exam- | Exam- | Exam- | Exam- | Exam- | Exam- | Exam- | Exam- |
| | ple 1 | ple 2 | ple 3 | ple 4 | ple 5 | ple 6 | ple 7 | ple 8 | ple 1 | ple 2 | ple 3 | ple 4 |
| Bias | 94 | 93 | 91 | 90 | 89 | 89 | 90 | 85 | 83 | 77 | 76 | 65 |
| alignment | | | | | | | | | | | | |
| (%) | | | | | | | | | | | | |
| Center | 88 | 82 | 86 | 84 | 88 | 85 | 85 | 76 | 64 | 70 | 65 | 61 |
| alignment | | | | | | | | | | | | |
| (%) | | | | | | | | | | | | |

As shown in Table 4, Examples 1 to 8, which are curable compositions according to one embodiment, include a compound represented by Chemical Formula 1 as a photopolymerization initiator, and therefore have superior dielectrophoretic properties compared to Comparative Examples 1 to 4, which include a compound having a structure different from Chemical Formula 1 as a photopolymerization initiator.

From this, it can be seen that the curable composition according to one embodiment has excellent dispersion stability and dielectrophoretic properties of semiconductor nanorods, and is suitable for large-area coating and panel production.

The present disclosure is not limited to the embodiments mentioned above, and can be manufactured in various suitable different forms, and those having ordinary skill in the technical field to which this disclosure belongs will understand that it can be implemented in other specific forms without changing the technical idea or essential features of this disclosure.

Therefore, the embodiments described above should be understood in all respects as illustrative and not restrictive.

### EXPLANATION OF SYMBOLS

1 electrode
2 semiconductor nanorod
3 fixed organic layer

What is claimed is:

1. A curable composition, comprising:
(A) a semiconductor nanorod;
(B) a photopolymerizable monomer comprising a compound having an unsaturated carbon-carbon double bond;
(C) a photopolymerization initiator comprising a compound represented by the following Chemical Formula 1; and
(D) a solvent 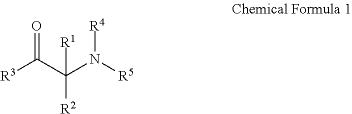
in Chemical Formula 1,
R¹ to R⁵ each independently represent a hydrogen atom, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C20 aryl group, or a substituted or unsubstituted C3 to C20 heterocyclic group, and
R⁴ and R⁵ can optionally fuse with each other to form a ring.

2. The curable composition of claim 1, wherein:
the compound represented by Chemical Formula 1 is represented by the following Chemical Formula 1-1 or Formula 1-2: 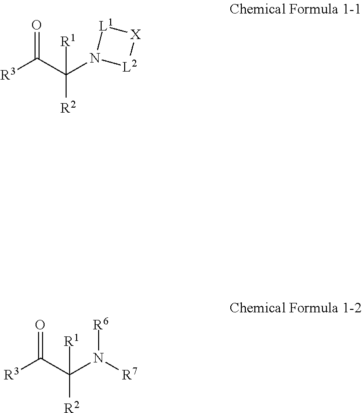
in Chemical Formula 1-1 and Chemical Formula 1-2,
X is CR^{a}R^{b} (R^{a} and R^{b} are each independently a hydrogen atom, a halogen atom, a substituted or unsubstituted C1 to C10 alkyl group), O, or S,
L¹ and L² are each independently a substituted or unsubstituted C1 to C20 alkylene group,
R¹ to R³ are each independently a hydrogen atom, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C20 an aryl group, or a substituted or unsubstituted C3 to C20 heterocyclic group, and
R⁶ and R⁷ are each independently a hydrogen atom, a substituted or unsubstituted C1 to C20 alkyl group, a substituted or unsubstituted C3 to C20 cycloalkyl group, or a substituted or unsubstituted C6 to C20 aryl group.

3. The curable composition of claim 1, wherein:
the compound represented by Chemical Formula 1 is a curable composition represented by the following Chemical Formula 1-1-1, Chemical Formula 1-2-1, or Chemical Formula 1-2-2:

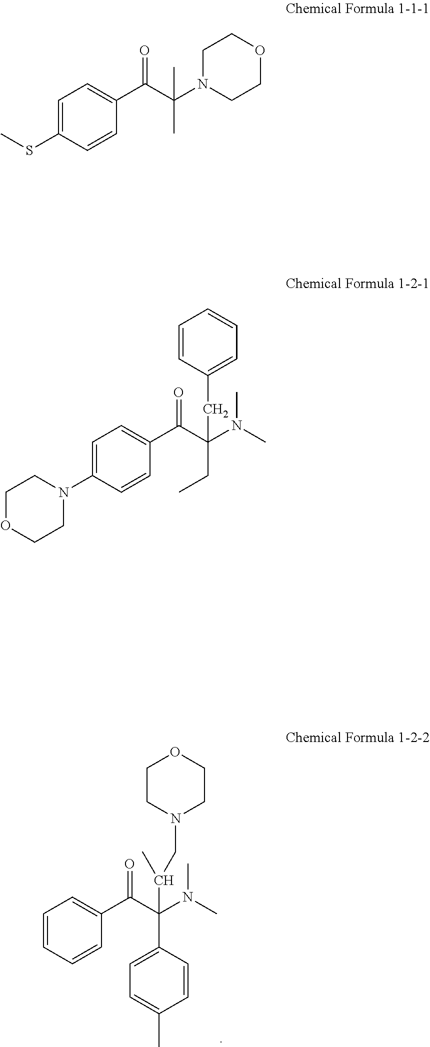 [SMILES: CSc1ccc(C(=O)C(C)(C)N2CCOCC2)cc1 ; CCC(Cc1ccccc1)(C(=O)c1ccc(N2CCOCC2)cc1)N(C)C ; Cc1ccc(C(C(=O)c2ccccc2)(C(C)CN2CCOCC2)N(C)C)cc1]

4. The curable composition of claim 1, wherein:
the semiconductor nanorod is a curable composition having a diameter of 300 nm to 900 nm.

5. The curable composition of claim 1, wherein:
the semiconductor nanorod is a curable composition having a length of 3.5 μm to 5 μm.

6. The curable composition of claim 1, wherein:
the semiconductor nanorod is a curable composition comprising a GaN-based compound, an InGaN-based compound, or a combination thereof.

7. The curable composition of claim 1, wherein:
the semiconductor nanorod is a curable composition whose surface is coated with a metal oxide.

8. The curable composition of claim 7, wherein:
the metal oxide comprises alumina, silica, or a combination thereof.

9. The curable composition of claim 1, wherein:
in the curable composition, relative to the total amount of the curable composition:
the (A) semiconductor nanorod is present at 0.01 weight % to 10 weight %;
the (B) photopolymerizable monomer is present at 1 weight % to 40 weight %;
the (C) light curing initiator is present at 0.1 weight % to 5 weight %; and
the (D) solvent is the remaining amount.

10. The curable composition of claim 1, wherein:
the curable composition comprises malonic acid, 3-amino-1,2-propanediol, a silane-based coupling agent, a leveling agent, a fluorine-based surfactant, or a combination thereof.

11. A film produced using the curable composition of claim 1.

12. A display device comprising the film of claim 11.
